(19) United States
(12) Patent Application Publication
(10) Pub. No.: US 2017/0075759 A1
(43) Pub. Date: Mar. 16, 2017

(54) MEMORY SYSTEM

(71) Applicant: KABUSHIKI KAISHA TOSHIBA, Minato-ku (JP)

(72) Inventor: Takahiro OTSUKA, Yokohama (JP)

(73) Assignee: KABUSHIKI KAISHA TOSHIBA, Minato-ku (JP)

(21) Appl. No.: 15/069,014

(22) Filed: Mar. 14, 2016

Related U.S. Application Data
(60) Provisional application No. 62/217,433, filed on Sep. 11, 2015.

(51) Int. Cl. G06F 11/10; G11C 29/52

(52) U.S. Cl. CPC G06F 11/1068; G11C 29/52

(57) ABSTRACT

According to one embodiment, a memory system includes: a memory cell arrange array capable of storing data in units of pages; a first latch which stores data in units of pages; a second latch which stores data in units of pages; a third latch which stores data in units of pages; and an ECC circuit which performs error correction processing for the data in the memory cell array in units of sectors smaller than pages. The memory system reads a first sector from the memory cell array in a first time, or reads the first sector from the third latch in a second time shorter than the first time. The ECC circuit determines whether or not the first sector contains an error.

### CROSS REFERENCE TO RELATED APPLICATIONS

This application claims the benefit of U.S. Provisional Application No. 62/217,433, filed Sep. 11, 2015, the entire contents of which are incorporated herein by reference.

### FIELD

Embodiments described herein relate generally to a memory system.

### BACKGROUND

Storage capacity increases in accordance with the miniaturization of semiconductor memory devices.

### BRIEF DESCRIPTION OF THE DRAWINGS

FIG. 1 is a block diagram schematically showing a basic configuration of a memory system according to a first embodiment.

FIG. 2 shows a data structure corresponding to one page.

FIG. 3 illustrates a threshold distribution of memory cell transistors of the memory system of the first embodiment.

FIG. 4 is a flowchart illustrating a read operation of the memory system of the first embodiment.

FIG. 5 is a flowchart illustrating a read operation of the memory system of the first embodiment.

FIG. 6 is a command sequence illustrating a read operation of the memory system of the first embodiment.

FIG. 7 illustrates a specific example of a read operation of the memory system of the first embodiment.

FIG. 8 illustrates a specific example of a read operation of the memory system of the first embodiment.

FIG. 9 illustrates a specific example of a read operation of the memory system of the first embodiment.

FIG. 10 illustrates a specific example of a read operation of the memory system of the first embodiment.

FIG. 11A illustrates how a read operation of a memory system according to a comparative example is performed with time.

FIG. 11B illustrates how a read operation of the memory system of the first embodiment is performed with time.

FIG. 12 is a flowchart illustrating a read operation of a memory system according to a second embodiment.

FIG. 13 is a flowchart illustrating a read operation of the memory system of the second embodiment.

FIG. 14 is a flowchart illustrating a read operation of the memory system of the second embodiment.

FIG. 15 is a flowchart illustrating a read operation of a memory system according to a third embodiment.

### DETAILED DESCRIPTION

In general, according to one embodiment, a memory system includes: a memory cell arrange array capable of storing data in units of pages; a first latch which stores data in units of pages; a second latch which stores data in units of pages; a third latch which stores data in units of pages; and an ECC circuit which performs error correction processing for the data in the memory cell array in units of sectors smaller than pages, wherein the memory system reads a first sector from the memory cell array in a first time, or reads the first sector from the third latch in a second time shorter than the first time, and the ECC circuit determines whether or not the first sector contains an error.

A description will now be given of embodiments with reference to the accompanying drawings. In the description below, the same reference numerals will be used throughout the drawings to denote similar or corresponding portions.

### <1> First Embodiment

A memory system according to the first embodiment will be described. In the description below, reference will be made to the case where the semiconductor storage device provided with a memory system is realized as a planar NAND flash memory.

### <1-1> Configuration

### <1-1-1> Memory System

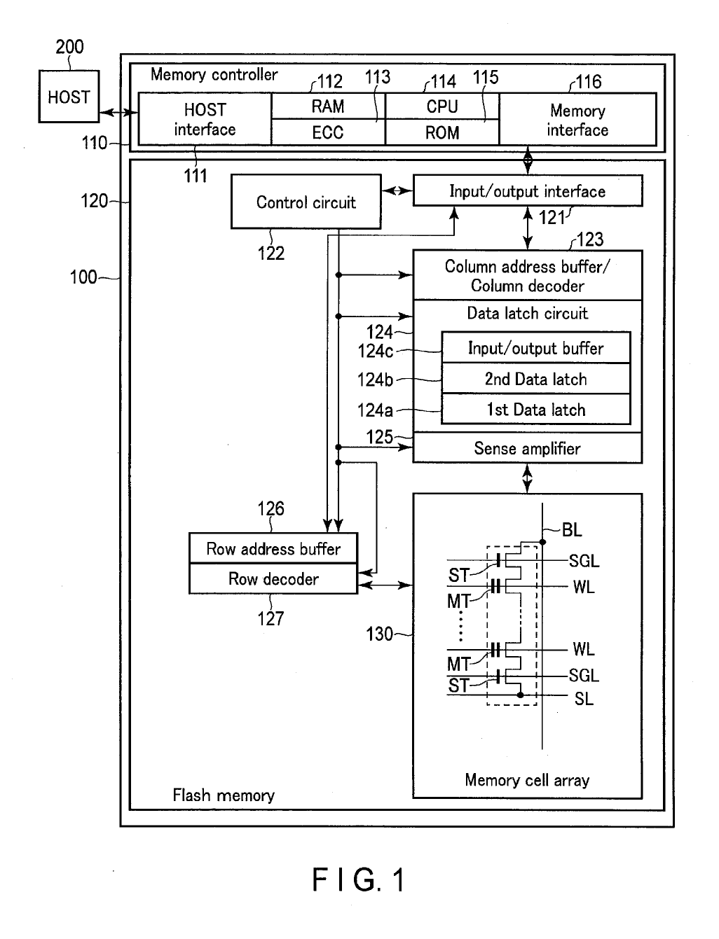

First, a configuration of a memory system according to the present embodiment will be described with reference to FIG. 1.

As shown in FIG. 1, a memory system 100 comprises a memory controller 110 and a NAND flash memory 120. The memory controller 110 and the NAND flash memory 120 may constitute one semiconductor device, for example, by combining them together. Examples of such a semiconductor device are a memory card such as an SD™ card and a solid state drive (SSD). The memory system 100 may also comprise a host device 200.

### <1-1-2> Memory Controller

The memory controller 110 includes a host interface 111, a random access memory (RAM) 112, an error correction code (ECC) circuit 113, a central processing unit (CPU) 114, a read only memory (ROM) 115, and a memory interface 116.

The memory controller 110 outputs a command required for an operation of the NAND flash memory 120. The memory controller 110 supplies the command to the NAND flash memory 120 to read data from the NAND flash memory 120, write data in the NAN flash memory 120, or erase data from the NAND flash memory 120.

The host interface 111 is connected to a host device 200 (such as a personal computer) through a data bus. Through the host interface 111, data are transmitted and received between the host device 200 and the memory system 100.

For example, RAM 112 is a volatile memory and stores operation programs for enabling the CPU 114 to operate.

The ECC circuit 113 corrects errors in the data read from the NAND flash memory 120 (the operation will be referred to as error correction processing). The ECC circuit 113 performs error correction processing, using a low density parity check (LDPC) code (which will be referred to simply as an error correcting code or as an LDPC parity).

A brief description will be given as to how the ECC circuit operates 113. Upon receipt of data from the host device 200, the ECC circuit 113 adds an error correcting code to the received data. The ECC circuit 113 supplies the data, including the error correcting code added thereto, to the memory interface 116, for example. The ECC circuit 113 receives data output from the NAND flash memory 120, via the memory interface 116. The ECC circuit 113 performs error correction for the received data from the NAND flash memory 120, using an error correcting code. The ECC circuit 113 supplies the error-corrected data to the host interface 111.

The CPU 114 controls the overall operations of the memory system 100. The CPU 114 controls the NAND flash memory 120 based on the data stored in RAM 112 and ROM 115. As described above, the CPU 114 controls the overall operations of the memory system 100 even if the host device 200 is included in the memory system 100.

ROM 115 is a volatile memory and stores, for example, operation programs for enabling the CPU 114 to operate.

The memoryain interface 116 is connected to the NAND flash memory 120 via a data bus. The memory interface 116 controls the connection between the memory controller 110 and the NAND flash memory 120.

### <1-1-3> NAND Flash Memory

The NAND flash memory 120 includes an input/output interface 121, a control circuit 122, a column address buffer/column decoder 123, a data latch circuit 124, a sense amplifier 125, a row address buffer 126, a row decoder 127, and a memory cell array 130.

The memory cell array 130 includes a plurality of bit lines BL, a plurality of word lines WL, and a source line SL. The memory cell array 130 is formed by a plurality of blocks BLK, in each of which a matrix of electrically-rewritable memory cell transistors (also referred to simply as memory cells) MC is arranged. The memory cell transistor MC, for example, includes a stacked gate including a control gate electrode and a charge accumulation layer (such as a floating gate electrode), and stores binary, or multivalued, data based on a change of the threshold of a transistor determined based on the amount of charge injected into the floating gate electrode. The memory cell transistor MC may have a Metal-Oxide-Nitride-Oxide-Silicon (MONOS) structure which traps electrons by a nitride film.

The configuration of the memory cell array 110 is disclosed in U.S. patent application Ser. No. 12/397,711 filed Mar. 3, 2009 and entitled “SEMICONDUCTOR MEMORY DEVICE HAVING PLURALITY OF TYPES OF MEMORIES INTEGRATED ON ONE CHIP.” In addition, the configuration thereof is disclosed in U.S. patent application Ser. No. 13/451,185 filed Apr. 19, 2012 and entitled “SEMICONDUCTOR MEMORY DEVICE INCLUDING STACKD GATE HAVING CHARGE ACCUMULATION LAYER AND CONTROL GATE AND METHOD OF WRITING DATA TO SEMICONDUCTOR MEMORY DEVICE,” in U.S. patent application Ser. No. 12/405,626 filed Mar. 17, 2009 and entitled “NONVOLATILE SEMICONDUCTOR MEMORY ELEMENT, NONVOLATILE SEMICONDUCTOR MEMORY, AND METHOD FOR OPERATING NONVOLATILE SEMICONDUCTOR MEMORY ELEMENT,” and in U.S. patent application Ser. No. 09/956,986 filed Sep. 21, 2001 and entitled “NONVOLATILE SEMICONDUCTOR MEMORY DEVICE HAVING ELEMENT ISOLATING REGION OF TRENCH TYPE AND METHOD OF MANUFACTURING THE SAME.” The entire descriptions of these patent applications are incorporated herein by reference.

When data is read out, the sense amplifier 125 senses data, read from the memory cell transistor MC and supplied to a bit line, at a SEN node (not shown). Data is read from the memory cell arrays 130 and written therein in units of a plurality of memory cell transistors (in units of pages, as will be described later). The sense amplifier 125 receives a bit line selection signal supplied thereto from the column address buffer/column decoder 123, and one of bit lines BL is selected and driven through the use of a bit line selection transistor (not shown).

The data latch circuit 124 includes a first data latch 124a, a second data latch 124b, and an input/output buffer 124c (which may be referred to as a data latch). Each of these is formed of an SRAM or the like. The first data latch 124a, the second data latch 124b and the input/output buffer 124c store, for example, data supplied by the memory controller 110 and a verification result sensed by the sense amplifier 125. Each of the first data latch 124a, second data latch 124b and input/output buffer 124c is configured to retain data corresponding to one page. The definition of “page” will be described later.

The column address buffer/column decoder 123 temporarily stores a column address signal which is supplied thereto from the memory controller 110 via the input/output interface 121. The address buffer/column decoder 123 supplies the sense amplifier 125 with a selection signal which selects one of the bit lines BL in accordance with the column address signal.

The row address decoder 127 decodes a row address signal input via the row address buffer decoder 126, and selects and drives a word line WL and selection gate lines SGD and SGS of the memory cell array 130. The row decoder 127 includes a portion configured to select a block of memory cell arrays 130 and a portion configured to select a page.

The NAND flash memory 120 of the first embodiment comprises an external input/output terminal I/O, not shown, and data is transmitted and received between the input/output interface 121 and the memory controller 110 by way of the external input/output terminal I/O. The address signal input via the external input/output terminal I/O is supplied to the row address decoder 127 and the column address buffer/column decoder 123 by way of the row address buffer 126.

The control circuit 122 controls the sequence control of data programming and erasing and read operations based on various external signals supplied thereto from the memory controller 110 (such as a chip enable signal CEn, a write enable signal WEn, a read enable signal REn, a command latch enable signal CLE, an address latch enable signal ALE, etc.).

### <1-1-4> Page

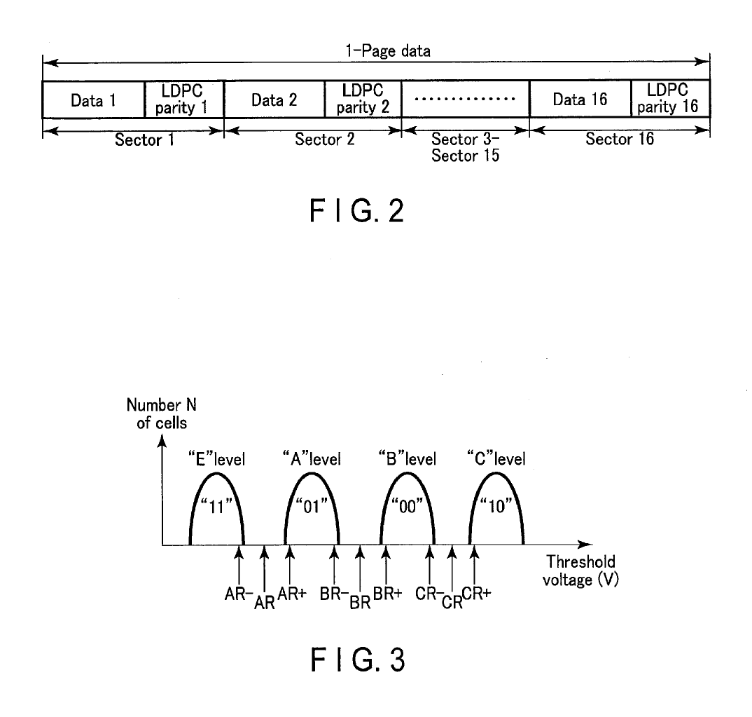

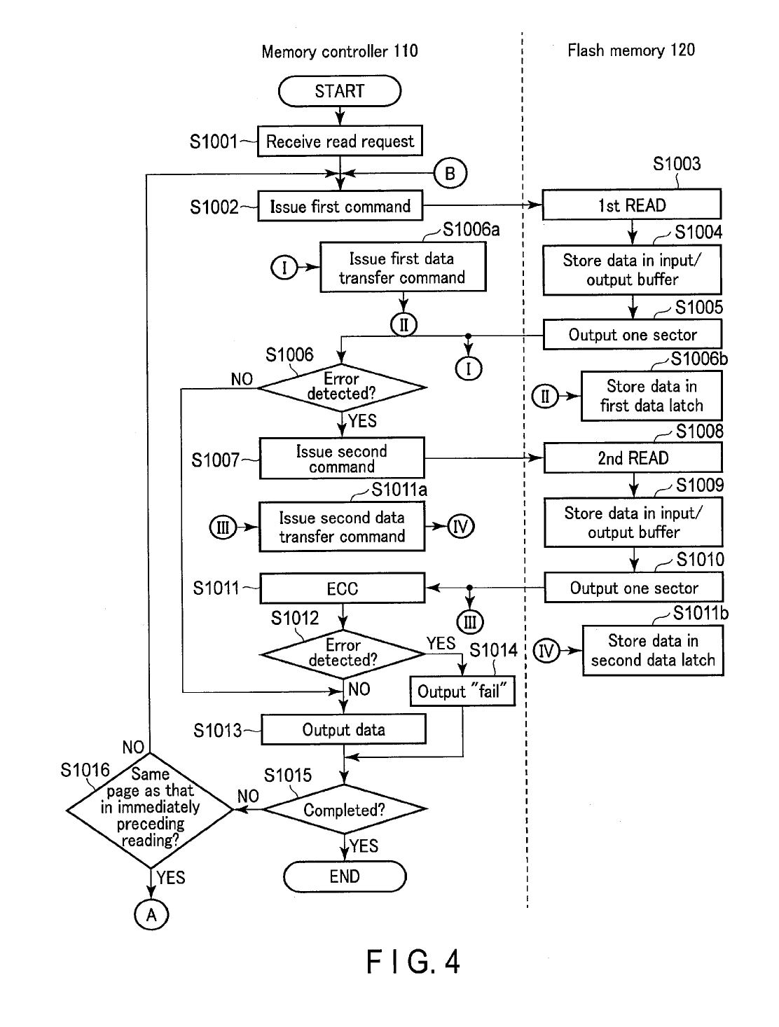

In the present embodiment, data are collectively read from memory cell transistors MC commonly connected to a word line WL in a block BLK (the unit of data read at a time may be referred to as a “page”). As shown in FIG. 2, one-page data according to the present embodiment includes a number of sectors (for example, sector 1 to sector 16). A “sector” is a unit for which the ECC circuit 113 can correct errors at a time. Each sector includes data and an LDPC parity.

A “page” can be defined as a part of the memory space formed by the memory cells connected to the same word line.

A schematic description will be given as to how a sector is generated. Upon receipt of data from the host device 200, the ECC circuit 113 divides the received data into pieces (data 1 to data 16). The ECC circuit 113 generates an LDPC parity (LDPC parity 1) based on one of divided pieces of data (data 1). The ECC circuit 113 assigns LDPC parity 1 to data 1. In this manner, sector 1 including data 1 and LDPC parity 1 is generated. Likewise, the ECC circuit 113 generates LDPC parity 2 to LDPC parity 16 and assigns them to data 2 to data 16, respectively. As should be apparent from the above, data and an LDPC parity corresponding to the data constitute a sector. The ECC circuit 113 supplies each sector to the NAND flash memory 120.

A schematic description will be given of the error correction processing performed for each sector. Upon receipt of sector 1 from the NAND flash memory 120, the ECC circuit 113 performs error correction processing for data 1 based on LDPC parity 1. Likewise, upon receipt of sector 2 to sector 16, the ECC circuit 113 performs error correction processing for data 2 to data 16 based on LDPC parity 2 to LDPC parity 16.

In FIG. 2, one page is shown as comprising 16 sectors by way of example, but this in no way restricts the embodiment.

### <1-1-5> Threshold Distribution of Memory Cell Transistors

A description will be given with reference to FIG. 3 of the threshold distribution of the memory cell transistors MC of the semiconductor storage device according to the present embodiment.

The memory cell transistors MC of the embodiment can retain, for example, 2-bit data in accordance with their thresholds. In the present embodiment, the 2-bit data are labeled as “E” level, “A” level, “B” level and “C” level in the ascending order of threshold. Each level has a 2-bit address, namely an upper bit and a lower bit. For example, “E” level is numbered as “11”, “A” level is numbered as “10”, “B” level is numbered as “00”, and “C” level is numbered as “01.” In “11”, “10”, “00” and “01”, the figure on the left side is an upper bit and the figure on the right side is a lower bit. The unit of writing lower-bit data will be referred to as “lower-bit page.” The unit of writing upper-bit data will be referred to as “upper-bit page.”

The “E” level corresponds to the threshold distribution of a state where data is erased, and is expressed as a negative value (it may be expressed as a positive value). The “E” level is lower than read level “AR.” The “A” to “C” levels correspond to the threshold distributions of a state where charges are injected into the charge accumulation layers of memory cell transistors MC. The thresholds of memory cell transistors MC of the “A” level are higher than read level “AR” and are lower than read level “BR” (BR>AR). The thresholds of memory cell transistors MC of the “B” level are higher than read level “BR” and are lower than read level “CR” (CR>BR). The thresholds of memory cell transistors MC of the “C” level are higher than read level “CR.”

As can be seen from the above, each memory cell transistor MC can have four threshold levels and can retain 2-bit data (4-level data). Needless to say, the memory cell transistors MC may retain data of not less than 3 bits or may retain 1-bit data.

### <1-2> Operation

### <1-2-1> Summary of 1st READ and 2nd READ

The four threshold distributions described above may vary due to the degradation of the memory cell transistors MC. If the threshold distributions vary, unintended data may be read at the time of data read, lowering the reliability of the data. To solve this problem, the error correction processing has to be performed for the read data. When error correction processing is performed, the memory controller 110 adds the threshold voltage information of memory cell transistors MC to the read data so that error correction processing can be performed with accuracy. The threshold voltage information represents where in each threshold distribution (E, A, B and C) the threshold voltage value of a memory transistor MC is. (For example, the threshold voltage information represents whether the threshold voltage value is near the center of threshold distribution A, is on the right side of threshold distribution A, or is on the left side of threshold distribution A.) In other words, the threshold voltage information is information representing “probability” of read data. The reading of the threshold voltage information will be referred to as “2nd READ” in the descriptions below. The reading of ordinary data (“11”, “01”, “00” and “10”) will be referred to as “1st READ” in the descriptions below.

The ECC circuit 113 performs error correction processing, using read results (sectors) of the 1st READ and 2nd READ.

### <1-2-2>1st READ

At the time of the 1st READ, the control circuit 122 applies voltage “AR” to a selected word line WL. At the time of the 1st READ, the control circuit 122 applies voltage “CR” to a selected word line WL. Where the threshold voltage of memory transistor MC is higher than voltage “AR” and lower than voltage “CR”, the control circuit 122 determines that the lower bit stored in memory cell transistor MC is “0” data. Where the threshold voltage of memory transistor MC is lower than voltage “AR” and is higher than voltage “CR”, the control circuit 122 determines that the lower bit stored in memory cell transistor MC is “1” data.

At the time of the 1st READ, the control circuit 122 applies voltage “BR” to a selected word line WL. Where the threshold voltage of memory transistor MC is lower than voltage “BR”, the control circuit 122 determines that the upper bit stored in memory cell transistor MC is “1” data. Where the threshold voltage of memory transistor MC is higher than voltage “BR”, the control circuit 122 determines that the upper bit stored in memory cell transistor MC is “0” data.

### <1-2-3>2nd READ

In the 2nd READ, the control circuit 122 applies voltage AR−(AR−<AR), voltage AR+(AR<AR+), voltage BR−(AR+<BR−<BR), voltage BR+(BR<BR+), voltage CR−(BR+<CR−<CR) or voltage CR+(CR<CR+) to a selected word line WL, thereby generating threshold voltage information.

### <1-2-4> Read Operation According to Present Embodiment

A description will be given of a read operation of the memory system according to the present embodiment.

### [Step S1001]

When the host device 200 issues a read request to the memory system 100, the memory controller 110 receives the read request by way of the host interface 111.

### [Step S1002]

Upon receipt of the read request, the CPU 114 issues an address corresponding to the first command and read request and supplies that address to the flash memory 120.

### [Step S1003]

The control circuit 122 receives the address and the first command by way of the input/output interface 121, and upon receipt of them performs the 1st READ operation for the memory cell array 130.

[Step S1004]

The control circuit 122 stores 1-page data read by the 1st READ operation in the input/output buffer 124c.

To be more specific, the control circuit 122 stores the 1-page data read from the memory cell array 130 in the input/output buffer 124c.

### [Step S1005]

Based on the received address, the control circuit 122 supplies one sector, which is included in the 1-page data stored in the input/output buffer 124c, to the memory controller 110.

### [Step S1006a]

The CPU 114 issues a first data transfer command to the flash memory 120.

### [Step S1006b]

Upon receipt of the first data transfer command, the control circuit 122 performs a data transfer operation.

To be more specific, the control circuit 122 transfers the data from the input/output buffer 124c to the first data latch 124a.

In the present embodiment, the memory controller 110 issues the first data transfer command, and in response to this the data stored in the input/output buffer 124c is transferred to the first data latch 124a. Alternatively, however, the flash memory 120 may be configured such that the data stored in the input/output buffer 124c is transferred to the first data latch 124a in step S1004, subject to the receipt of the first command.

The control circuit 122 may store the data read from the memory cell array 130 in the first data latch 124a at any time desired, only if a read operation other than the 1st READ is not started.

### [Step S1006]

The CPU 114 stores the sector received via the memory interface 116 in a first storage area 112a (not shown) of RAM 112.

Based on the LDPC parity included in the sector stored in RAM 112, the ECC circuit 113 determines whether the data included in the sector contains an error.

### [Step S1007]

The ECC circuit 113 uses both the result of the 1st READ and the result of the 2nd READ when it performs error correction processing. When the ECC circuit 113 determines that the data in the received sector contains an error (YES in step S1006), the memory controller 110 executes the 2nd READ operation for the flash memory 120. To be more specific, the CPU 114 issues a second command to the flash memory 120, along with the address issued in step S1002.

### [Step S1008]

Upon receipt of the address and the second command, the control circuit 122 performs the 2nd READ operation for the memory cell array 130.

### [Step S1009]

The control circuit 122 stores 1-page data read by the 2nd READ operation in the input/output buffer 124c.

When step S1009 is executed, the 1-page data read by the 1st READ operation is stored in the first data latch 124a.

### [Step S1010]

Based on the received address, the control circuit 122 supplies one sector, which is included in the 1-page data stored in the input/output buffer 124c, to the memory controller 110.

### [Step S1011a]

The CPU 114 issues a second data transfer command to the flash memory 120.

### [Step S1011b]

Upon receipt of the second data transfer command, the control circuit 122 performs a data transfer operation.

To be more specific, the control circuit 122 transfers the data from the input/output buffer 124c to the second data latch 124b.

In the present embodiment, the memory controller 110 issues the second data transfer command, and in response to this the data stored in the input/output buffer 124c is transferred to the second data latch 124a. Alternatively, however, the flash memory 120 may be configured such that the data stored in the input/output buffer 124c is transferred to the second data latch 124n in step S1009, subject to the receipt of the second command.

The control circuit 122 may store the data read from the memory cell array 130 in the second data latch 124b at any time desired.

### [Step S1011]

The CPU 114 stores one sector received via the memory interface 116 in a second storage area 112b (not shown) of RAM 112.

The ECC circuit 113 performs error correction processing for correcting an error included in the sector, based on the data read in 1st READ and the 2nd READ and stored in the first storage area 112a and the second storage area 112b.

### [Step S1012]

The ECC circuit 113 determines whether the data for which the error correction processing is performed contains an error. In other words, the ECC circuit 113 determines whether an error in the data has been corrected by ECC.

### [Step S1013]

Where the ECC circuit 113 determines that the received sector does not contain an error (NO in step S1006) or that the data for which the ECC circuit 113 performs error correction processing in step S1012 does not contain an error (NO in step S1012), the data is output to the host device 200 via the host interface 111.

### [Step S1014]

Where the ECC circuit 113 determines that the received sector contains an error (YES in step S1012), the ECC circuit 113 outputs “fail” representing that the error correction processing for data ends in failure and supplies it to the host device 200.

### [Step S1015]

The CPU determines 114 whether read request made by the host device 200 has been completed. Where the CPU 114 determines that the read request made by the host device 200 has been completed (YES in step S1015), the read operation is terminated.

### [Step S1016]

Where the CPU 114 determines that the read request made by the host device 200 has not yet been completed (NO in step S1015), the CPU 114 refers to the address for the immediately preceding read operation and the address for the next read operation. The CPU 114 determines whether the page for which the read operation is performed last is the same as the page for which the read operation is performed next.

If the CPU 114 determines that the page for which the read operation is performed last is not the same as the page for which the read operation is performed next (NO in step S1016), then the CPU 114 performs the operation of step S1002.

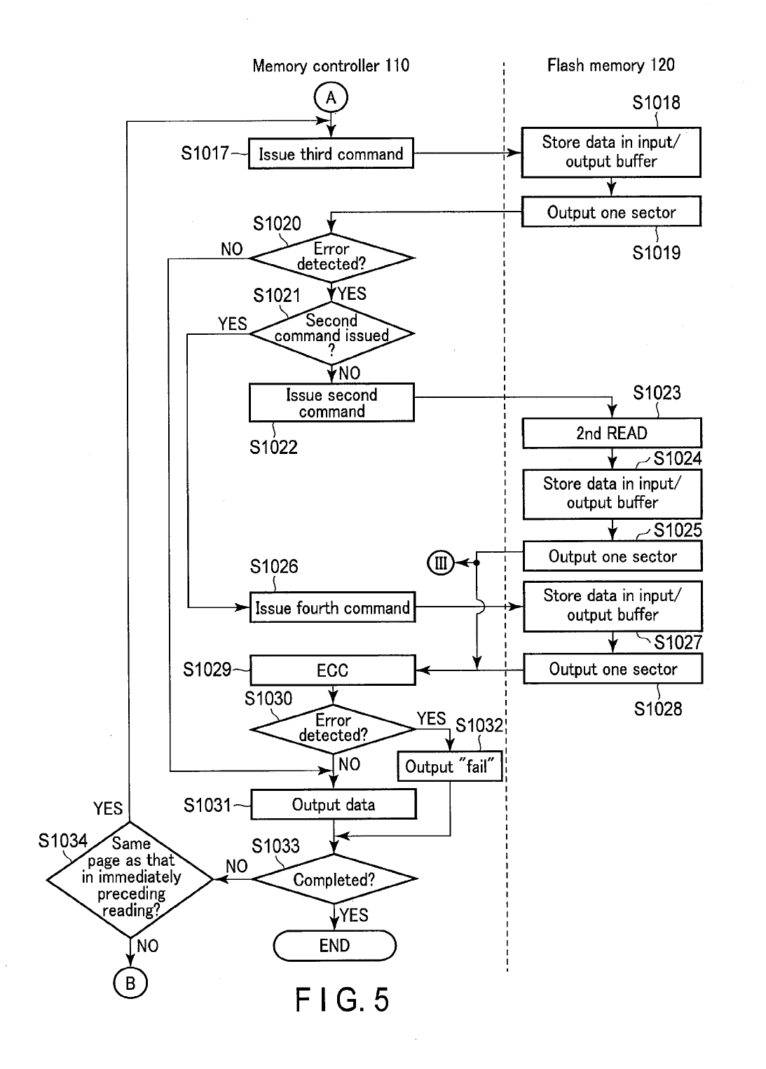

The steps subsequent to step S1016 will be described with reference to FIG. 5.

### [Step S1017]

If the CPU 114 determines that the page for which the read operation is performed last is the same as the page for which the read operation is performed next (YES in step S1016), then the CPU 114 issues an address and a third command to the flash memory 120.

### [Step S1018]

Upon receipt of the third command, the control circuit 122 stores the data stored in the first data latch 124a in the input/output buffer 124c.

### [Step S1019]

The control circuit 122 supplies one sector, which is included in the 1-page data stored in the input/output buffer 124c, to the memory controller 110.

### [Step S1020]

The memory controller 110 performs an operation similar to that of step S1006.

### [Step S1021]

The CPU 114 determines whether the second command was issued in the immediately preceding read operation.

### [Step S1022] to [Step S1025]

Where the CPU 114 determines that the second command was not issued in the immediately preceding read operation (NO in step S1021), the CPU 114 performs an operation similar to that of step S1007, and the flash memory 120 performs operations similar to those of steps S1008 to S1010.

### [Step S1026]

If the CPU 114 determines that the second command was issued in the immediately preceding read operation (YES in step S1021), then the CPU 114 issues an address and a fourth command to the flash memory 120.

### [Step S1027]

Upon receipt of the fourth command, the control circuit 122 stores the data stored in the second data latch 124b in the input/output buffer 124c.

### [Step S1028]

The control circuit 122 supplies one sector, which is included in the 1-page data stored in the input/output buffer 124c, to the memory controller 110.

### [Step S1029] and [Step S1030]

The memory controller 110 performs operations similar to those of steps S1011 and S1012.

### [Step S1031]

The memory controller 110 performs an operation similar to that of step S1013.

### [Step S1032]

The memory controller 110 performs an operation similar to that of step S1014.

### [Step S1033]

The CPU 114 performs an operation similar to that of step S1015.

### [Step S1034]

The CPU 114 performs an operation similar to that of step S1016.

### <1-2-5> Specific Example

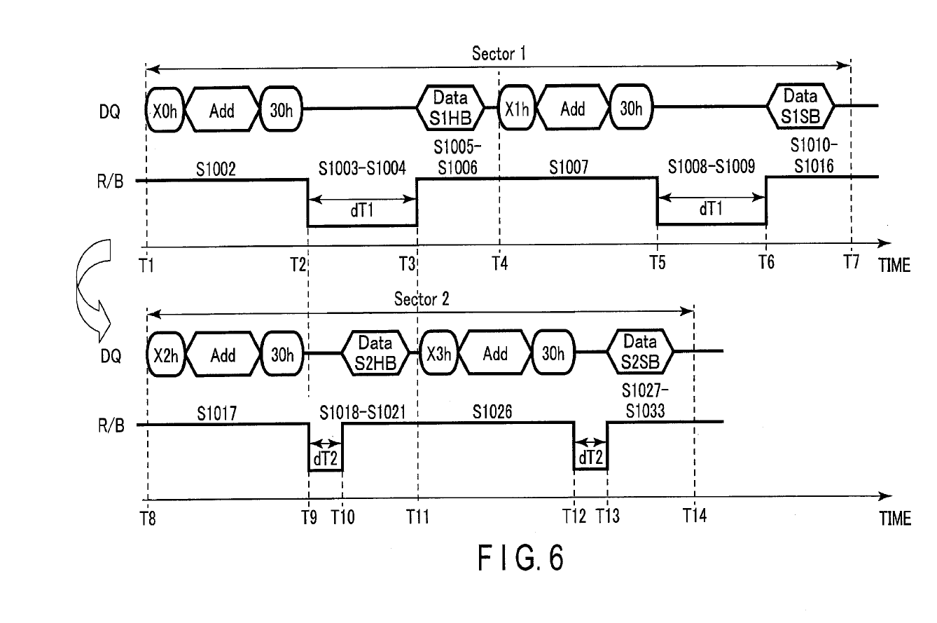

A specific example of the read operation mentioned above will be described with reference to FIGS. 6-10. In connection with the specific example, reference will be made to the case where sector 1 of page x (x: a natural number) and sector 2 of page x are sequentially read. In connection with the specific example, reference will be made to the case where data read by the 1st READ and the data read by the 3rd READ contain an error.

### [Time T1]

At time T1, the memory controller 110 issues a first command (“X0h”), an address (Add) and a “30h” command on the basis of a read request made by the host device 200, so as to read sector 1 of page x of the memory cell array 130 (the operation corresponding to step S1002).

### [Time T2]

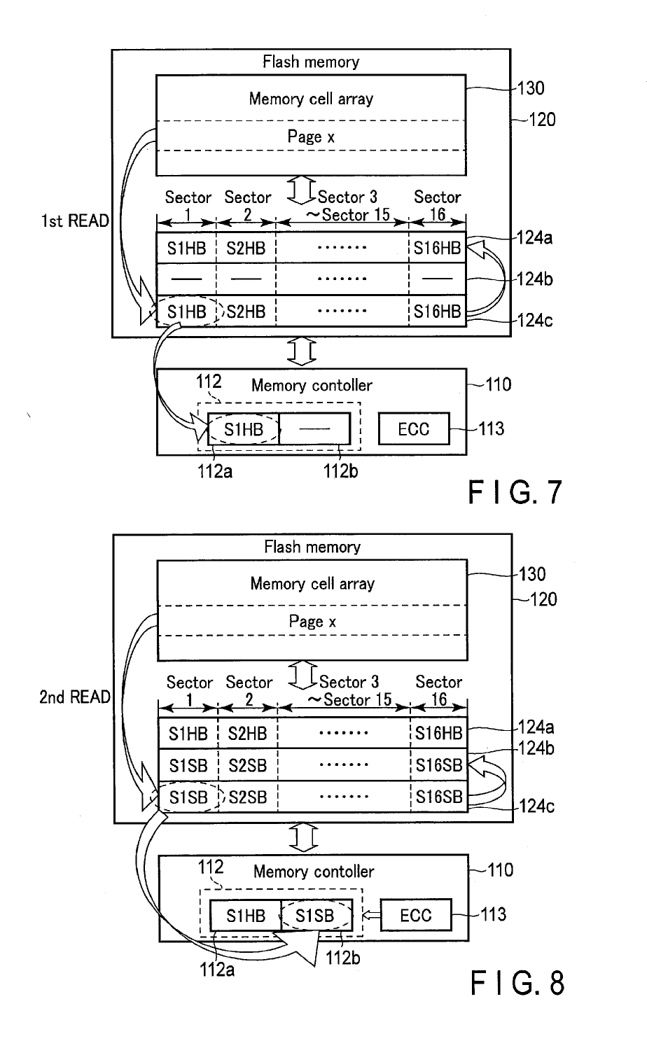

As shown in FIG. 7, the flash memory 120 starts the 1st READ operation when it successfully receives the first command (“X0h”), address (Add) and “30h” command from the memory controller 110.

To be more specific, the flash memory 120 performs the 1st READ operation for the memory cell array 130 based on the received address, and reads data S1HB to data S16HB from page x (the operation corresponding to step S1003). Data S1HB is obtained as a result of the 1st READ performed for sector 1. In other words, data S1HB to data S16HB correspond to sectors 1 to 16 read by the 1st READ operation.

The flash memory 120 stores data on page x in the input/output buffer 124c. The flash memory 120 transfers the data on page x from the input/output buffer 124c to the first data latch 124a (the operation corresponding to step S1004).

It is assumed that the period of time required for steps S1003 and S1004 is time dT1.

### [Time T3]

As shown in FIGS. 6 and 7, where the address designated by the memory controller 110 indicates page x and sector 1, the flash memory 120 supplies data S1HB (sector 1) stored in the input/output buffer 124c to the memory controller 110 (the operation corresponding to step S1005).

Data S1HB is stored in the first storage area 112a of RAM 112, and the ECC circuit 113 determines whether or not an error exists (the operation corresponding to step S1006).

### [Time T4]

Where the ECC circuit 113 determines that data S1HB contains an error, the memory controller 110 issues a second command (“X1h”), an address (Add) and a “30h” command so as to perform 2nd READ for page x and sector 1 of the memory cell array 130 (the operatin corresponding to step S1007).

### [Time T5]

As shown in FIG. 8, the flash memory 120 starts the 2nd READ operation when it successfully receives the second command (“X1h”), address (Add) and “30h” command from the memory controller 110.

To be more specific, the flash memory 120 performs the 2nd READ operation for the memory cell array 130 based on the received address, and reads data S1SB to data S16SB from page x (the operation corresponding to step S1008). Data S1SB to data S16SB correspond to sectors 1 to 16 read by the 2nd READ operation.

The flash memory 120 stores the result of the 2nd READ in the input/output buffer 124c. The flash memory 120 transfers the result of the 2nd READ from the input/output buffer 124c to the second data latch 124b (the operation corresponding to step S1009). It is assumed that the period of time required for steps S1008 and S1009 is time dT1.

### [Time T6]

As shown in FIGS. 6 and 8, the flash memory 120 supplies data S1SB (sector 1) stored in the input/output buffer 124c to the memory controller 110 (the operation corresponding to step S1010).

Data S1SB is stored in the second storage area 112b of RAM 112. The ECC circuit 113 performs ECC, using data S1HB stored in the first storage area 112a of RAM 112 and data S1SB stored in the second storage area 112b (the operation corresponding to step S1011).

Where the ECC circuit 113 determines that the data for which the error correction processing has been performed contains no error, the host interface 111 supplies the data subjected to the error correction processing to the host device 200 (the operation corresponding to steps S1012 and S1013).

Where the ECC circuit 113 determines that the data for which the error correction processing has been performed contains an error, the ECC circuit 113 outputs “fail” representing that the error correction processing for data ends in failure and supplies it to the host device 200 (the operation corresponding to steps S1012 and S1014).

### [Time T7]

At time T7, the error correction processing for the data in sector 1 comes to an end. That is, where an error exists in sector 1, the period of time required for the read operation to be completed is from time T1 to time T7.

### [Time T8]

In connection with the specific example, sector 1 of page x and sector 2 of page x are sequentially read. At time TB, therefore, the memory controller 110 issues a third command (“X2h”), an address (Add) and a “30h” command, so as to read sector 2 of page x of the memory cell array 130 (the operation corresponding to step S1015 to S1017).

### [Time T9]

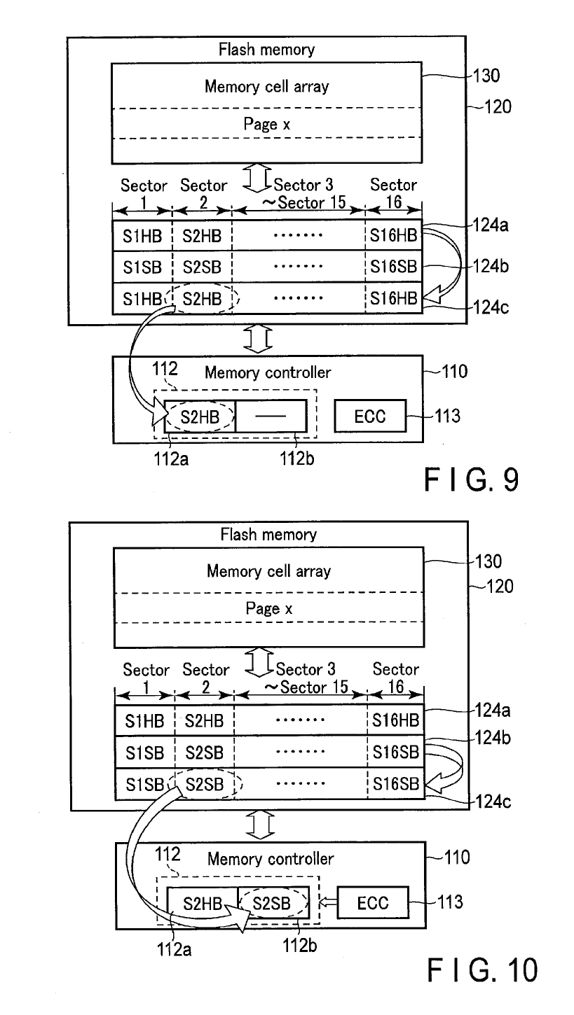

As shown in FIG. 9, the flash memory 120 starts the 3rd READ operation when it successfully receives the third command (“X2h”), address (Add) and “30h” command from the memory controller 110.

To be more specific, the flash memory 120 transfers the data on page x from the first data latch 124a to the input/output buffer 124c (the operation corresponding to step S1018).

It is assumed here that the period of time required for step S1018 is time dT2 (dT1>dT2). The period of time required for the operation related to the third command (step S1018) is shorter than the period of time related to the first command (steps S1003 and S1004).

### [Time T10]

As shown in FIGS. 6 and 9, where the address designated by the memory controller 110 indicates sector 2 of page x, the flash memory 120 supplies data S2HB (sector 2) stored in the input/output buffer 124c to the memory controller 110 (the operation corresponding to step S1019).

Data S2HB is stored in the first storage area 112a of RAM 112, and the ECC circuit 113 determines whether or not an error exists (the operation corresponding to step S1020).

### [Time T11]

Where the ECC circuit 113 determines that data S2HB contains an error, the memory controller 110 issues a fourth command (“X3h”), an address (Add) and a “30h” command with respect to sector 2 of page x of the memory cell array (the operation corresponding to step S1026).

### [Time T12]

As shown in FIG. 10, the flash memory 120 starts the 4th READ operation when it successfully receives the fourth command (“X3h”), address (Add) and “30h” command from the memory controller 110.

To be more specific, the flash memory 120 transfers the data on page x from the second data latch 124b to the input/output buffer 124c (the operation corresponding to step S1027).

It is assumed here that the period of time required for step S1027 is time dT2.

### [Time T13]

As shown in FIGS. 6 and 10, the flash memory 120 supplies data S2SB (sector 2) stored in the input/output buffer 124c to the memory controller 110 (the operation corresponding to step S1028).

Data S2SB is stored in the second storage area 112b of RAM 112. The ECC circuit 113 performs ECC, using data S2HB stored in the first storage area 112a of RAM 112 and data S2SB stored in the second storage area 112b (the operation corresponding to step S1029).

Where the ECC circuit 113 determines that the data for which the error correction processing has been performed contains no error, the host interface 111 supplies the data subjected to the error correction processing to the host device 200 (the operation corresponding to steps S1030 and S1031).

Where the ECC circuit 113 determines that the data for which the error correction processing has been performed contains an error, the ECC circuit 113 outputs “fail” representing that the error correction processing for data ends in failure and supplies it to the host device 200 (the operation corresponding to steps S1030 and S1032).

### [Time T14]

At time T14, the error correction processing for sector 2 comes to an end. That is, where an error exists in sector 2, the period of time required for the read operation to be completed is from time T8 to time T14.

As can be seen from the foregoing, where sectors 1 and 2 of page x are sequentially read, the period of time required for reading sector 2 is shorter than the period of time required for reading sector 1 by (2□dT1−2□dT2).

### <1-3> Advantage

According to the embodiment described above, the flash memory 120 stores the result of the 1st READ of page x in the first data latch 124a and stores the result of 2nd READ of page x in the second data latch 124b. In accordance with a request made by the memory controller 110, the flash memory 120 supplies either the data stored in the first data latch 124a or the data stored in the second data latch 124b to the memory controller 110. Since data is kept stored in the first data latch 124a and the second data latch 124b, the operation of reading data from the memory cell array 130 does not have to be performed many times.

There may be a case where the size of data subjected to error correction processing is smaller than the page size of the flash memory. In such a case, data is not stored in the first data latch 124a or the second data latch 124b, and the 1st READ and 2nd READ are repeatedly performed for reading a number of sectors from a given page. A problem caused by the repetitive execution of the 1st READ and the 2nd READ will be explained, with a specific example being referred to.

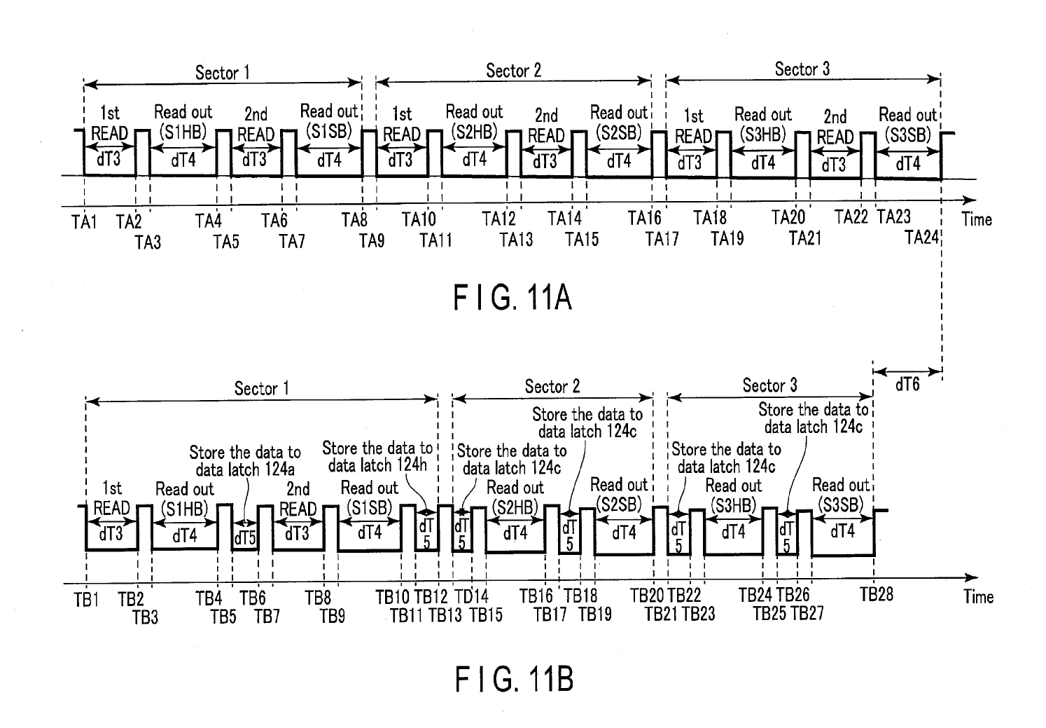

First, a comparative example where data is not stored in the first data latch 124a or the second data latch 124b will be described with reference to FIG. 11A. In the description below, reference will be made to the case where the memory system 100 reads sectors 1 to 3 of page x.

As shown in FIG. 11A, where the memory system 100 determines that sector 1 read by 1st READ contains an error, the memory system 100 executes 2nd READ. The period of time required for the 1st READ or the 2nd READ is dT3. The period of time required for supplying the read result of the 1st READ or 2nd READ to the memory controller 110 is time dT4. Since no data is stored in the first data latch 124a or the second data latch 124b, the operation which the memory system 100 performs for sectors 2 and 3 is similar to that it performs for sector 1.

The memory system 100 according to the present embodiment will be described with reference to FIG. 11B. As shown in FIG. 11B, when the memory system 100 performs the 1st READ for page x, the read result is stored in the first data latch 124a (times TB5−TB6). Where the memory system 100 determines that sector 1 read by the 1st READ contains an error, the memory system 100 executes 2nd READ. The memory system 100 executes 2nd READ for page x, and the read result is stored in the second data latch 124b (times TB11−TB12).

The period of time required for the read result to be stored in the first data latch 124a or the second data latch 124b is dT5 (dT5<dT3). As compared with time period dT3, time period dT5 is sufficiently short.

In the memory system 100, data on page x is stored in both the first data latch 124a and the second data latch 124b. Therefore, neither the 1st READ nor the 2nd READ has to be executed when another sector on page x is read. To be more specific, when another sector of page x is read, the memory system 100 transfers the data stored in the first data latch 124a to the input/output buffer 124c, instead of executing the 1st READ. The period of time required for the data stored in the first data latch 124a to be transferred to the input/output buffer 124c is time period dT5.

As can be seen from FIGS. 11A and 11B, the period of time required for the memory system of the present embodiment to read sectors 1-3 is shorter than the period of time required for the memory system of the comparative example to read sectors 1-3 by time dT6.

In the memory system 100 of the present embodiment, the first data latch 124a and the second data latch 124b are utilized in such a manner that the number of times data is read from the memory cell array 130 can be reduced. Where a number of sectors are read from the same page, a shorter time is required for reading data from the memory cell array 130, and less power is required for reading data from the memory cell array. It is therefore possible to provide a memory system of high quality.

### <2> Second Embodiment

The second embodiment will be described. The semiconductor device of the second embodiment differs from the semiconductor of the first embodiment in terms of the timing when the result of 1st READ is stored in the first data latch 124a. The basic configuration and operation of the semiconductor memory device according to the second embodiment are the same as those of the semiconductor memory device according to the first embodiment. Therefore, descriptions of features described in relation to the first embodiment and features easily inferable from the first embodiment will be omitted.

### <2-1> Operation

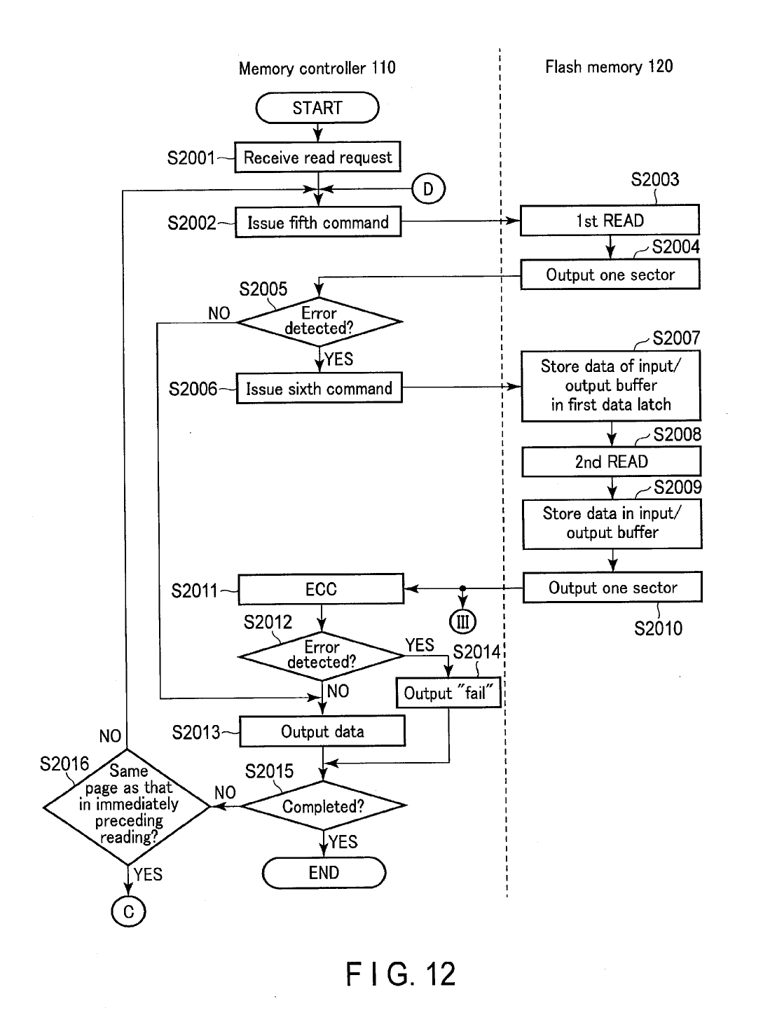

A description will be given with reference to FIGS. 12 to 14 of a read operation of the memory system according to the present embodiment.

### [Step S2001]

The memory controller 110 performs an operation similar to that of step S1001.

### [Step S2002]

Upon receipt of a read request from the host device 200, the CPU 114 issues a fifth command and an address based on the read request and supplies these to the flash memory 120.

### [Step S2003]

Upon receipt of the address and the fifth command, the control circuit 122 performs the 1st READ operation for the memory cell array 130.

### [Step S2004] and [Step S2005]

The flash memory 120 performs an operation similar to that of step S1005. The memory controller 110 performs an operation similar to that of step S1006.

### [Step S2006]

When the ECC circuit 113 determines that the data in the received sector contains an error (YES in step S2005), the memory controller 110 executes the 2nd READ operation for the flash memory 120. To be more specific, the CPU 114 issues a sixth command to the flash memory 120, along with the address issued in step S2002.

### [Step S2007]

Upon receipt of the sixth command, the control circuit 122 stores the data read by the 1st READ in both the first data latch 124a and the input/output buffer 124c.

To be more specific, the control circuit 122 stores the data read from the memory cell array 130 in the input/output buffer 124c, and stores the data stored in the input/output buffer 124c in the first data latch 124a.

Alternatively, the control circuit 122 may store the data read from the memory cell array 130 in the first data latch 124a, and store the data stored in the first data latch 124a in the input/output buffer 124c.

### [Step S2008]

After step S2007, the control circuit 122 performs the 2nd READ operation for the memory cell array 130 based on the received address.

### [Step S2009] to [Step S2016]

The flash memory 120 performs operations similar to those of steps S1009 and S1010. The memory controller 110 performs operations similar to those of steps S1011 to S1016.

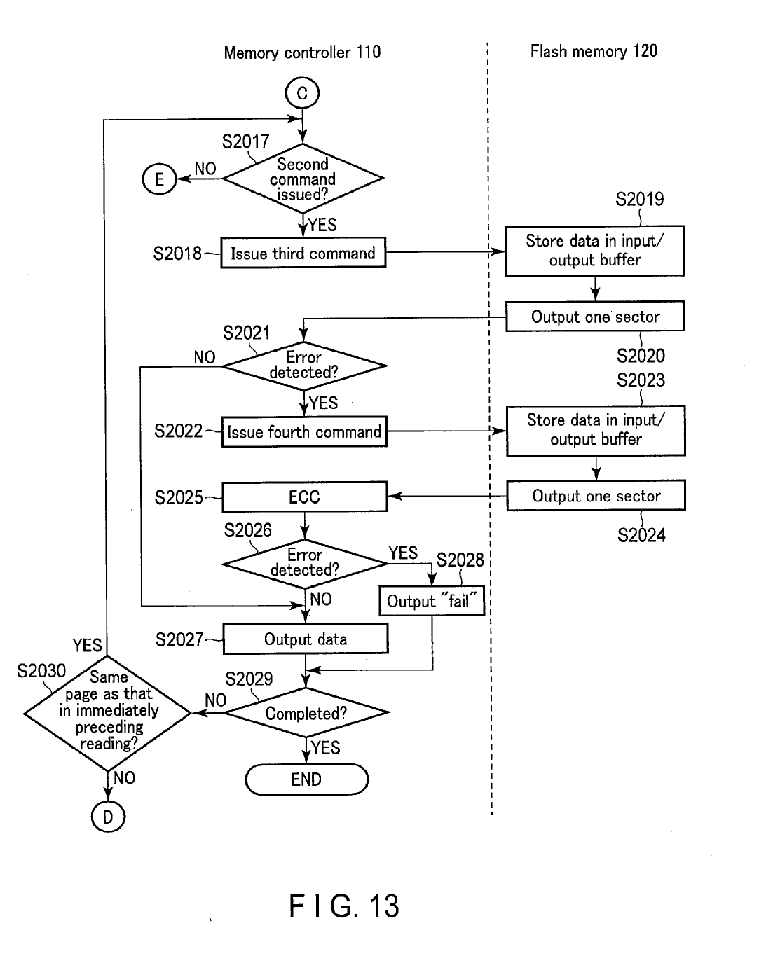

The steps subsequent to step S2016 will be described with reference to FIG. 13.

### [Step S2017]

The memory controller 110 performs an operation similar to that of step S1021.

### [Step S2018]

If the CPU 114 determines that the second command was issued in the immediately preceding read operation (YES in step S2017), then the CPU 114 issues an address and a third command to the flash memory 120.

### [Step S2019] to [Step S2030]

In steps S2019 and S2020, the flash memory 120 performs operations similar to those of steps S1018 and S1019. In steps S2021 and S2022, the memory controller 110 performs operations similar to those of steps S1020 and S1022. In steps S2023 and S2024, the flash memory 120 performs operations similar to those of steps S1027 and S1028. In steps S2025 to S2030, the memory controller 110 performs operations similar to those of steps S1029 to S1034.

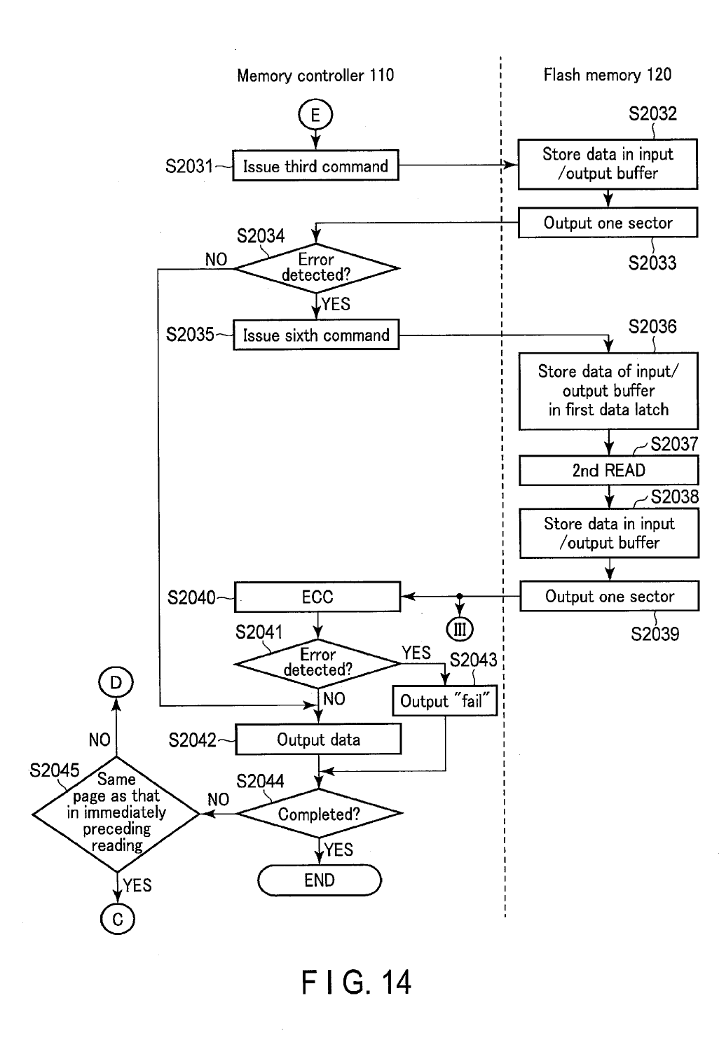

The steps subsequent to step S2030 will be described with reference to FIG. 14.

### [Step S2031] to [Step S2045]

Where the CPU 114 determines that the second command was not issued in the immediately preceding read operation (NO in step S2017), the memory controller 110 performs an operation similar to that of step S2018. In steps S2032 and S2033, the flash memory 120 performs operations similar to those of steps S2019 and S2020. In steps S2034 and S2035, the memory controller 110 performs operations similar to those of steps S2005 and S2006.

In steps S2036 to S2039, the flash memory 120 performs operations similar to those of steps S2007 to S2010. In steps S2040 to S2045, the memory controller 110 performs operations similar to those of steps S1011 to S1016.

### <2-2> Advantages

The embodiment described above achieves similar advantages to those of the first embodiment even though the timing when the result of the 1st READ is stored in the first data latch 124a is different from the timing described in relation to the first embodiment.

### <3> Third Embodiment

A description will be given of the third embodiment. The semiconductor memory device of the third embodiment differs from the semiconductor memory devices of the first and second embodiments in that it switches operation modes based on the number of times data is written in the memory cell array 130 or the number of times data is erased therefrom. The basic configuration and operation of the semiconductor memory device according to the third embodiment are the same as those of the semiconductor memory devices according to the first and second embodiments. Therefore, descriptions of features described in relation to the first embodiment and features easily inferable from the first embodiment will be omitted.

### <3-1> Operation

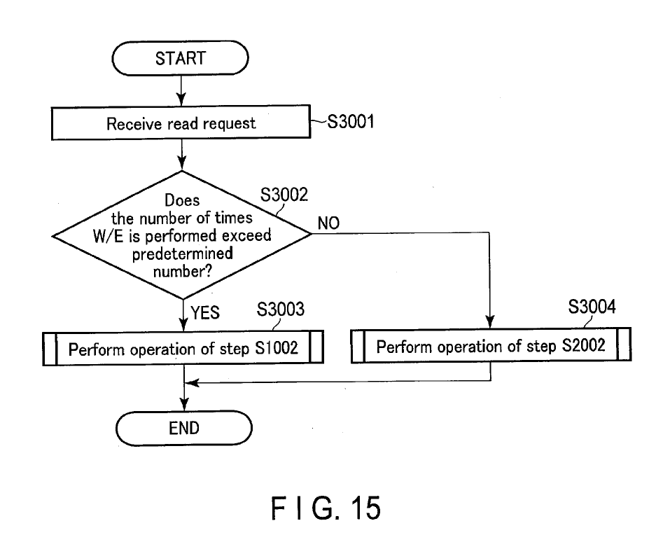

A description will be given with reference to FIG. 15 of a read operation of the memory system 1 according to the present embodiment.

### [Step S3001]

The memory controller 110 performs an operation similar to that of step S1001.

### [Step S3002]

Upon receipt of a read request from the host device 200, the CPU 114 determines whether the number of times write/erase is performed at a write address exceeds a predetermined value. The number of times write/erase is performed is counted, for example, by a memory controller 110, and count information may be stored in RAM 112, for example.

### [Step S3003]

Where the CPU 114 determines that the number of times write/erase is performed at the write address exceeds the predetermined value (YES in step S3002), the CPU performs operations of steps S1002 to S1034.

### [Step S3004]

Where the CPU 114 determines that the number of times write/erase is performed at the write address does not exceed the predetermined value (NO in step S3002), the CPU 114 performs operations of steps S2002-S2045.

### <3-2> Advantages

The embodiment described above achieves similar advantages to those of the first embodiment even though it switches operation modes based on the number of times write/erase is performed for the memory cell array 130.

### <4> Modification

In relation to the above-described embodiments, reference was made to the case where the memory cell array 130 is a planar memory. Even if the memory cell array 130 has a three-dimensional laminated structure, the advantages obtained thereby are similar to those of each of the aforesaid embodiments.

The configuration of the memory cell array 110 is disclosed in U.S. patent application Ser. No. 12/407,403 filed 19 Mar. 2009 and entitled “THREE DIMENSIONAL STACKED NONVOLATILE SEMICONDUCTOR MEMORY.” In addition, the configuration thereof is disclosed in U.S. patent application Ser. No. 12/406,524 filed 18 Mar. 2009 and entitled “Three Dimensional Stacked Nonvolatile Semiconductor Memory”, in U.S. patent application Ser. No. 13/816,799 filed 22 Sep. 2011 and entitled “NONVOLATILE SEMICONDUCTOR MEMORY DEVICE”, and in U.S. patent application Ser. No. 12/532,030 filed 23 Mar. 2009 and entitled “SEMICONDUCTOR MEMORY AND METHOD FOR MANUFACTURING THE SAME.” The entire descriptions of these patent applications are incorporated herein by reference.

In each of the foregoing embodiments, the data latch circuit 124 comprises three data latches, but this does not restrict the embodiments. The data latch circuit 124 may comprise four or more data latches.

In each of the foregoing embodiments, the first data latch 124a stores the reading result of 1st READ, and the second data latch 124b stores the reading result of 2nd READ. However, this configuration does not restrict the embodiments, and a proper modification may be made, as needed.

In each of the foregoing embodiments, one page is made up of 16 sectors, but this configuration does not restrict the embodiments. One page may include not more than 15 sectors or may include not less than 17 sectors.

In each of the foregoing embodiments:

### (1) Read Operation

The voltage applied to a selected word line in an A level read operation is, for example, between 0V and 0.55V. The voltage is not limited to this range, and may be any one of between 0.1V and 0.24V, between 0.21V and 0.31V, between 0.31V and 0.4V, between 0.4V and 0.5V and between 0.5V and 0.55V.

The voltage applied to a selected word line in a B level read operation is, for example, between 1.5V and 2.3V. The voltage is not limited to this range, and may be any one of between 1.65V and 1.8V, between 1.8V and 1.95V, between 1.95V and 2.1V, and between 2.1V and 2.3V.

The voltage applied to a selected word line in a C level read operation is, for example, between 3.0V and 4.0V. The voltage is not limited to this range, and may be any one of between 3.0V and 3.2V, between 3.2V and 3.4V, between 3.4V and 3.5V, between 3.5V and 3.6V and between 3.6V and 4.0V.

The read operation time (tR) may be, for example, between 25 μs and 38 μs, between 38 μs and 70 μs or between 70 μs and 80 μs.

### (2) Write Operation

As described above, the write operation includes a program operation and a verification operation. In the write operation,

The voltage first applied to a selected word line in the program operation is, for example, between 13.7V and 14.3V. The voltage is not limited to this range, and may be either one of between 13.7V and 14.0V and between 14.0V and 14.6V.

The voltage first applied to a selected word line when data is written to odd-numbered word lines may differ from the voltage first applied to a selected word line when data is written to even-numbered word lines.

When the Incremental Step Pulse Program (ISPP) method is used for the program operation, the step-up voltage is approximately 0.5V, for example.

The voltage applied to a non-selected word line is, for example, between 6.0V and 7.3V. The voltage is not limited to this range, and may be between 7.3V and 8.4V or not higher than 6.0V.

The applied pass voltage may be changed depending on whether the non-selected word line is an odd-number word line or an even-number word line.

The write operation time (tProg) may be, for example, between 1700 μs and 1800 μs, between 1800 μs and 1900 μs or between 1900 us and 2000 μs.

### (3) Erase Operation

The voltage first applied to a well which is formed in an upper part of the semiconductor substrate and above which the memory cell is provided is, for example, between 12V and 13.6V. The voltage is not limited to this range, and may be, for example, between 13.6V and 14.8V, between 14.8V and 19.0V, between 19.0V and 19.8V or between 19.8V and 21V.

The erase operation time (tErase) may be, for example, between 3000 μs and 4000 μs, between 4000 μs and 5000 μs or between 4000 μs and 9000 μs.

### (4) Structure of Memory Cell

The structure of the memory cell includes a charge accumulation layer provided on the semiconductor substrate (silicon substrate) via a tunnel insulation film having a thickness of 4 to 10 nm. The charge accumulation layer may have a laminated structure of an insulation film of SiN or SiON having a thickness of 2 to 3 nm and polysilicon having a thickness of 3 to 8 nm. The polysilicon may include a metal such as Ru. An insulation film in provided on the charge accumulation layer. This insulation film includes a silicon dioxide film having a thickness of 4 to 10 nm, which is interposed between a lower High-k film having a thickness of 3 to 10 nm and a higher High-k film having a thickness of 4 to 10 nm, for example. An example of the High-k film is HfO. The thickness of the silicon dioxide film may be greater than that of the High-k film. On the insulation film, a control electrode having a thickness of 30 nm to 70 nm is formed via a material having a thickness of 3 to 10 nm. The material for adjusting the work function is a metal-oxide film such as TaO and a metal-nitride film such as TaN. For example, W may be used for the control electrode.

In addition, an air gap may be formed between memory cells.

While certain embodiments have been described, these embodiments have been presented by way of example only, and are not intended to limit the scope of the claims. Indeed, the novel methods and systems described herein may be embodied in a variety of other forms; furthermore, various omissions, substitutions and changes in the form of the methods and systems described herein may be made without departing from the spirit of the embodiments. The accompanying claims and their equivalents are intended to cover such forms or modifications as would fall within the scope and spirit of the embodiments.

What is claimed is:

1. A memory system comprising;
a memory cell array arrange capable of storing data in units of pages;
a first latch which stores data in units of pages;
a second latch which stores data in units of pages;
a third latch which stores data in units of pages; and
an ECC circuit which performs error correction processing for data in the memory cell array in units of sectors smaller than pages,
wherein the memory system reads a first sector from the memory cell array in a first time, or reads the first sector from the third latch in a second time shorter than the first time, and
the ECC circuit determines whether the read first sector contains an error.

2. The memory system of claim 1, wherein
the memory system reads a first sector from the memory cell if a page for which a read request is made is determined to be different from a page for which an immediately preceding read request is made, or reads the first sector from the first latch if the page for which the read request is made is determined to be the same as the page for which the immediately preceding read request is made, and
the ECC circuit determines whether the read first sector contains an error.

3. The memory system of claim 2, wherein
where the memory system performs a 1st READ operation for a first page of the memory cell array, the memory system stores a result of the 1st READ operation regarding the first page in both the first latch and the third latch, and
where the memory system performs a 2nd READ operation for the first page of the memory cell array, the memory system stores a result of the 2nd READ operation in both the second latch and the third latch.

4. The memory system of claim 3, wherein
the ECC circuit performs error correction processing for the first sector, using the result of the 1st READ operation regarding the first sector of the first page and the result of the 2nd READ operation regarding the first sector.

5. The memory system of claim 3, wherein
the memory system executes the 1st READ operation if the page for which the read request is made is determined to be different from the page for which the immediately preceding read request is made.

6. The memory system of claim 5, wherein
the ECC circuit executes the 2nd READ operation if the result of the 1st READ operation is determined to contain an error.

7. The memory system of claim 3, wherein
if the ECC circuit determines that the result of the 1st READ operation contains an error, the ECC circuit determines whether the result of the 2nd READ operation regarding the first sector contains an error, based on the data stored in the second latch.

8. The memory system of claim 1, wherein
the sector includes data and a parity regarding the data, and
the ECC circuit performs error correction processing for the data based on the parity.

9. The memory system of claim 8, wherein
the ECC circuit generates the parity based on externally received data, and stores the externally received data, with the parity added thereto, in the memory cell array as a sector.

10. The memory system of claim 3, wherein
a voltage applied to the memory cell array at a time of the 1st READ operation is different from a voltage applied to the memory cell at a time of the 2nd READ operation.

11. A memory device comprising:
a memory cell arrange array capable of storing data in units of pages;
a first latch which stores data in units of pages;
a second latch which stores data in units of pages;
a third latch which stores data in units of pages; and
an ECC circuit which performs error correction processing for the data in the memory cell array in units of sectors smaller than pages,
wherein
the memory device reads a first sector from the memory cell array in a first time, or reads the first sector from the third latch in a second time shorter than the first time, and
the ECC circuit determines whether the read first sector contains an error.

12. The memory device of claim 11, wherein
the memory device reads a first sector from the memory cell if a page for which a read request is made is determined to be different from a page for which an immediately preceding read request is made, or reads the first sector from the first latch if the page for which the read request is made is determined to be the same as the page for which the immediately preceding read request is made, and
the ECC circuit determines whether the read first sector contains an error.

13. The memory device of claim 12, wherein
where the memory device performs a 1st READ operation for a first page of the memory cell array, the memory device stores a result of the 1st READ operation regarding the first page in both the first latch and the third latch, and
where the memory device performs a 2nd READ operation for the first page of the memory cell array, the memory device stores a result of the 2nd READ operation regarding the first page in both the second latch and the third latch.

14. The memory device of claim 13, wherein
the ECC circuit performs error correction processing for the first sector, using the result of the 1st READ operation regarding the first sector of the first page and the result of the 2nd READ operation regarding the first sector.

15. The memory device of claim 13, wherein
the memory device executes the 1st READ operation if the page for which the read request is made is determined to be different from the page for which the immediately preceding read request is made.

16. The memory device of claim 15, wherein
if the ECC circuit determines that the result of the 1st READ operation contains an error, the memory device executes the 2nd READ operation.

17. The memory device of claim 13, wherein
if the ECC circuit determines that the result of the 1st READ operation contains an error, the ECC circuit determines whether the result of the 2nd READ operation regarding the first sector contains an error, based on the data stored in the second latch.

18. The memory device of claim 12, wherein
the sector includes data and a parity regarding the data, and
the ECC circuit performs error correction processing for the data based on the parity.

19. The memory device of claim 18, wherein
the ECC circuit generates the parity based on externally received data, and stores the externally received data, with the parity added thereto, in the memory cell array as a sector.

20. The memory device of claim 13, wherein
a voltage applied to the memory cell array at a time of the 1st READ operation is different from a voltage applied to the memory cell at a time of the 2nd READ operation.
